(19) United States
(12) Patent Application Publication
(10) Pub. No.: US 2022/0004908 A1
(43) Pub. Date: Jan. 6, 2022

(54) INFORMATION PROCESSING APPARATUS, INFORMATION PROCESSING SYSTEM, INFORMATION PROCESSING METHOD, AND NON-TRANSITORY COMPUTER READABLE MEDIUM STORING PROGRAM

(71) Applicants: NEC CORPORATION, Tokyo (JP); NATIONAL INSTITUTE OF ADVANCED INDUSTRIAL SCIENCE AND TECHNOLOGY, Tokyo (JP)

(72) Inventors: Keiichi KISAMORI, Tokyo (JP); Keisuke YAMAZAKI, Tokyo (JP)

(73) Assignees: NEC CORPORATION, Tokyo (JP); NATIONAL INSTITUTE OF ADVANCED INDUSTRIAL SCIENCE AND TECHNOLOGY, Tokyo (JP)

(21) Appl. No.: 17/295,294

(22) PCT Filed: Nov. 8, 2019
(86) PCT No.: PCT/JP2019/043821

§ 371 Date: May 19, 2021

(51) Int. Cl. G06N 7/00; G06F 30/27; G06K 9/00

(52) U.S. Cl. CPC G06N 7/005; G06K 9/0051; G06F 30/27

(57) ABSTRACT

An information processing apparatus includes: a corresponding data calculation unit configured to determine importance of each sample in accordance with a difference between a plurality of pieces of observation information observed when an input is given to an observation target and data of a second type generated by a simulator that simulates the observation target based on a sample of a parameter with respect to a plurality of samples and data of a first type indicating the input, and a degree of influence of the sample on distribution of parameters, and then calculate data that corresponds to the distribution of the parameters; a new parameter sample generation unit configured to generate a new sample of the parameters in accordance with predetermined processing using the data that corresponds to the distribution of the parameters; and an iteration control unit configured to perform control so as to repeat the above processing.

### TECHNICAL FIELD

The present disclosure relates to an information processing apparatus, an information processing system, an information processing method, and a program.

### BACKGROUND ART

Techniques for obtaining parameters of a model to be used for a simulation have been proposed. For example, Non-Patent Literature 1 proposes a method of performing point estimation of parameters by iteratively executing Kernel Approximate Bayesian Computation (Kernel ABC) and Kernel Herding.

There are literature other than the above one that disclose techniques related to that disclosed in the above literature.

In the technique disclosed in Patent Literature 1, a computer that operates as an adaptive controller determines, when the time evolution of a target physical system is described as a Markov process, an amount of control on a state of a physical system. Then this computer adaptively generates a control signal for controlling the status quantity of the physical system as a target value by a probabilistic sequential importance sampling method.

Patent Literature 2 discloses a wind power generation amount prediction apparatus that predicts an amount of power generated by wind power generation. This wind power generation amount prediction apparatus generates a polynomial that approximates data indicating a first wind speed and a first power generation amount at the first wind speed and calculates a maximum likelihood estimation value based on error variance of a second wind speed and a second power generation amount at the second wind speed, each of the second wind speed and the second power generation amount being calculated based on the above polynomial. Then the wind power generation amount prediction apparatus calculates an information criterion based on the maximum likelihood estimation value.

Patent Literature 3 discloses an information processing apparatus capable of executing a correct regression analysis even in a case where the mean and the variance of an objective variable are dependent on an explanatory variable taking continuous values.

### CITATION LIST

### Patent Literature

[Patent Literature 1] Japanese Unexamined Patent Application Publication No. 2005-084834
[Patent Literature 2] Japanese Unexamined Patent Application Publication No. 2017-141747
[Patent Literature 3] International Patent Publication No. WO 2011/074509

### Non-Patent Literature

[Non-Patent Literature 1] Takafumi Kajihara, Motonobu Kanagawa, Keisuke Yamazaki, Kenji Fukumizu, “Kernel Recursive ABC: Point Estimation with Intractable Likelihood”, arXiv: 1802.08404v2, 12 Jun. 2018.

### SUMMARY OF INVENTION

### Technical Problem

However, since the method disclosed in Non-Patent Literature 1 is a kind of maximum likelihood estimation method, point estimation is performed in this method. That is, estimation of distribution is not performed. Therefore, when, for example, parameters of a singular model are estimated, it is possible that an appropriate estimation may not be performed. In view of the above background, it has been required to propose a novel method capable of estimating a posterior distribution of parameters of a model. None of Patent Literature 1 to 3 discloses a method of estimating a posterior distribution of parameters of a model.

One of the objects that example embodiments herein disclosed will attain is to provide an information processing apparatus and the like capable of estimating a posterior distribution of parameters of a model.

### Solution to Problem

An information processing apparatus according to a first aspect includes:

corresponding data calculation means for determining importance of each sample in accordance with a difference between a plurality of pieces of observation information observed when an input is given to an observation target and data of a second type generated by a simulator that simulates the observation target based on a sample of a parameter with respect to a plurality of samples and data of a first type indicating the input, and a degree of influence of the sample on distribution of parameters, and then calculating data that corresponds to the distribution of the parameters;

new parameter sample generating means for generating a new sample of the parameters in accordance with predetermined processing using the data that corresponds to the distribution of the parameters; and

iteration control means for performing control so as to repeat the processing of the corresponding data calculation means and the processing of the new parameter sample generation means while performing control so that the corresponding data calculation means calculates data that corresponds to the distribution of the parameters using the data of the second type generated by the simulator with respect to the new sample generated by the new parameter sample generation means and the data of the first type.

An information processing system according to a second aspect includes:

the information processing apparatus; and

the simulator.

An information processing method according to a third aspect causes an information processing apparatus to execute:

first processing for determining importance of each sample in accordance with a difference between a plurality of pieces of observation information observed when an input is given to an observation target and data of a second type generated by a simulator that simulates the observation target based on a sample of a parameter with respect to a plurality of samples and data of a first type indicating the input, and a degree of influence of the sample on distribution of parameters, and then calculating data that corresponds to the distribution of the parameters;

second processing for generating a new sample of the parameters in accordance with predetermined processing using the data that corresponds to the distribution of the parameters; and

control so as to repeat the first processing and the second processing while performing control so as to execute the first processing using the data of the second type generated by the simulator with respect to the new sample generated by the second processing and the data of the first type.

A program according to a fourth aspect causes a computer to execute:

a corresponding data calculation step for determining importance of each sample in accordance with a difference between a plurality of pieces of observation information observed when an input is given to an observation target and data of a second type generated by a simulator that simulates the observation target based on a sample of a parameter with respect to a plurality of samples and data of a first type indicating the input, and a degree of influence of the sample on distribution of parameters, and then calculating data that corresponds to the distribution of the parameters;

a new parameter sample generating step for generating a new sample of the parameters in accordance with predetermined processing using the data that corresponds to the distribution of the parameters; and

an iteration control step for performing control so as to repeat the processing of the corresponding data calculation step and the processing of the new parameter sample generating step while performing control so as to execute the corresponding data calculation step using the data of the second type generated by the simulator with respect to the new sample generated by the new parameter sample generation step and the data of the first type.

### Advantageous Effects of Invention

According to the above aspects, it is possible to provide an information processing apparatus and the like capable of estimating a posterior distribution of parameters of a model.

### BRIEF DESCRIPTION OF DRAWINGS

FIG. 1 is a block diagram showing one example of a configuration of an information processing system according to an example embodiment;

FIG. 2 is a block diagram showing one example of a hardware configuration of an information processing apparatus according to the example embodiment;

FIG. 3 is a block diagram showing one example of a functional configuration of the information processing apparatus according to the example embodiment;

FIG. 4 is a flowchart showing one example of an operation of the information processing apparatus according to the example embodiment; and

FIG. 5 is a block diagram showing one example of a functional configuration of an information processing apparatus according to other example embodiments.

### DESCRIPTION OF EMBODIMENTS

While the present disclosure will be described using mathematical terms in order to facilitate understanding in each of the following example embodiments, each of these terms may not be necessarily defined mathematically. For example, a distance can be mathematically defined, like a Euclidean norm or one norm. The distance may instead be a value obtained by adding one to the above value. That is, terms that are used in the following example embodiments may not be terms that are mathematically defined.

Hereinafter, with reference to the drawings, example embodiments of the present disclosure will be described.

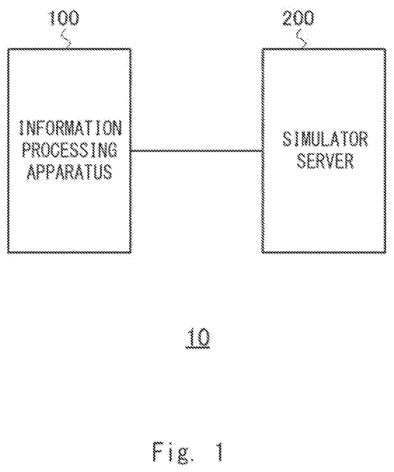

FIG. 1 is a block diagram showing one example of a configuration of an information processing system 10 according to an example embodiment. As shown in FIG. 1, the information processing system 10 includes an information processing apparatus 100 and a simulator server (simulator) 200.

The simulator server 200 is a simulator that receives an input of data of a first type and outputs data of a second type. That is, the simulator server 200 performs simulation processing of predicting the data of the second type from the data of the first type in accordance with a model defined by a parameter θ. The simulator server 200 executes, for example, processing of simulating processing (operation) in an observation target based on a sample of the parameter θ. The sample expresses the value of the parameter θ. Therefore, a plurality of samples express a plurality of examples (a plurality of pieces of data) set as the value of the parameter θ.

In the following description, the data of the first type is referred to as data X and the data of the second type is referred to as data Y. Further, observation data of the data X (observation data of the first type) is denoted by observation data Xⁿ and observation data of the data Y (observation data of the second type) is denoted by observation data Yⁿ, where n (n is a positive integer) denotes the number of pieces of observation data. Further, elements of the observation data Xⁿ are expressed by X₁, . . . , Xₙ and elements of the observation data Yⁿ are expressed by Y₁, . . . Yₙ. The information processing apparatus 100 acquires observation data (therefore, observation data that can be plot on the X-Y plane) in which the data Xᵢ (i is an integer within 1≤i≤n) is associated one to one with the data Yᵢ.

In the following description, the observation data may be referred to as observation information. Further, the observation data Yⁿ may be referred to as a plurality of pieces of observation information. In this case, each of the elements Y₁, . . . Yₙ may be indicated as observation information.

The observation data Xⁿ and Yⁿ are not limited to data of particular types and may be various kinds of data that have been actually measured. The measurement method to obtain the observation data is not limited to a specific method and various methods such as counting or measuring by a person like a user, sensing using a sensor or the like may be employed.

The elements of the observation data Xⁿ may indicate, for example, the state of components that compose the observation target. The elements of the observation data Yⁿ may indicate the state observed regarding the observation target using a sensor or the like. When, for example, the user desires to analyze the productivity of a manufacturing factory, the observation data Xⁿ may indicate the operation status of each facility in the manufacturing factory. The observation data Yⁿ may indicate the number of products manufactured in a line formed of a plurality of facilities. Further, the observation data Xⁿ may indicate a material that serves as a raw material of a product in the manufacturing factory. In this case, the material indicated by the observation data Xⁿ is subjected to one or more processes and then processed into a product. This product is not limited to a product of one kind and may be a plurality of products (e.g., a product A, a product B, and a by-product C). The observation data Yⁿ indicates, for example, the number of products A, the number of products B, and the number of by-products C (or an amount of production etc.)

The observation target and the observation data are not limited to the above-described example and may be, for example, a facility in a processing factory or a construction system in a case in which a facility is constructed.

The observation data Xⁿ and Yⁿ are generated independently in accordance with one real distribution q(x,y)=q(x)q(y|x). The statistical model for guessing a real model q(y|x) can be expressed by p(y|x,θ). The expression q(y|x) indicates the probability that an event y occurs when an event x is occurred. Further, “q(x)q(y|x)” indicates “q(x)×q(y|x)”. In the following description, for the sake of convenience of the description, the operator “x” indicating multiplication is omitted in accordance with mathematical practices.

The regression model r(x,θ) used by the simulator server 200 sets the value of the parameter θ and outputs the value of the data Y upon receiving the input of the value of the data X into the variable x. The simulator server 200 outputs the value of the data Y by performing, for example, an operation including the sample of the parameter θ on the data X (value of x). Note that a function that can be differentiated may not be necessarily used for the model. The simulator server 200 simulates the processing or the operation in the observation target.

When, for example, the observation target is a manufacturing factory, the simulator server 200 calculates the data Y by performing an operation in accordance with the value expressed by the parameter θ on the value of the data X, thereby simulating each process in the manufacturing factory. In this case, the parameter θ indicates, for example, a relation between an input and an output in each process. It can also be said that the parameter θ expresses a state in a process. The number of parameters θ is not limited to one and may be plural. That is, it can also be said that the regression model r(x,θ) collectively expresses the whole processing executed by the simulator server 200 using a symbol r.

Now, notation in Bayesian statistical inference will be defined. A minus log likelihood function Lₙ(0) is defined as shown in the following Expression (1).

$${L}_{n} ( θ ) = - \frac{1}{n} {\sum }_{i = 1}^{n} log p ( {Y}_{i} \vert {X}_{i} , θ ) \qquad < Expression ( 1 ) >$$

When the regression problem is modelled by a regression function that involves Gaussian noise, the statistical model (likelihood function) p(y|x,θ) is expressed as shown by the following Expression (2). The statistical model p(y|x,θ) is a model that indicates statistical properties regarding the regression model r(x,θ). However, the regression model r(x,θ) is not always expressed explicitly using a mathematical expression and may indicate, for example, processing such as a simulation in which x and θ are used as inputs and r(x,θ) is used as the output. In general, in the regression model, coefficients of an expression are determined so as to conform to given data. However, the regression model r(x,θ) according to this example embodiment may indicate a case in which such an expression is not given. That is, it is sufficient that the regression model r(x,θ) according to this example embodiment indicate information in which the inputs x and θ are associated with the output r (x,θ).

$$< Expression ( 2 ) > \\ \begin{matrix}p ( y \vert x , θ ) = \frac{1}{{\sqrt{2 {πσ}^{2}}}^{d}} exp \{ - \frac{1}{2 {σ}^{2}} {‖ y - r ( x , θ ) ‖}^{2} \} & \end{matrix}$$

The symbol σ (where σ>0) is a standard deviation of the Gaussian noise. That is, σ is a standard deviation of Gaussian noise in a model defined by a regression function that involves the Gaussian noise. Further, r(x,θ) is a value that the simulator server 200 calculates in accordance with the processing expressed by the regression model. The symbol d is the number of dimensions of X (i.e., the number of pieces of observation data described above). The symbol exp denotes an exponential function having a Napier's constant as a base. The symbol ∥ indicates calculation of a norm. The symbol π denotes a ratio of the circumference of a circle to its diameter.

Further, Bayes' theorem including the inverse temperature can be expressed as shown in the following Expression (3).

$$p ( θ \vert x , y ) = \frac{{p ( y \vert x , θ )}^{β} π ( θ )}{\int {p ( y \vert x , θ )}^{β} π ( θ ) d θ} \qquad < Expression ( 3 ) >$$

The symbol π(θ) is a prior distribution regarding the parameter θ. Further, p(θ|x,y) is a posterior distribution regarding the parameter θ. The symbol β (where β>0) is a parameter called an inverse temperature. According to the above Bayes' theorem, the posterior distribution of the parameters θ can be calculated based on the prior distribution π(θ) of the parameters θ and the likelihood function p(y|x,θ).

When the likelihood function p(y|x,θ) cannot be analytically expressed as a mathematical formula, that is, when the likelihood function p(y|x,θ) cannot be differentiated, it is difficult to calculate the posterior distribution of the parameters θ. Even in this case, however, the sample that follows the posterior distribution can be acquired by the following method. Hereinafter, acquisition of the sample data of the parameter θ using Kernel Approximate Bayesian Computation (Kernel ABC) and predetermined processing (Kernel Herding or the like) will be described.

The Kernel ABC is an algorithm that estimates a posterior distribution by calculating a kernel mean. In the Kernel ABC, the simulation is performed based on m pieces of sample data and the weight (importance) of the sample data of m parameters is determined based on the observation data observed regarding the observation target, whereby the posterior distribution can be obtained. For example, as the simulation results are more similar to the observation data, a weight that puts more emphasis on the parameters used for the results of the simulation is calculated. In contrast, as the simulation results are less similar to the observation data, a weight that puts less emphasis on the parameters used for the results of the simulation is calculated.

Kernel Herding (one example of predetermined processing) is an algorithm that acquires a sample that follows a posterior distribution from the kernel mean indicating the posterior distribution. Kernel Herding sequentially determines a sample that becomes the closest to the obtained kernel mean. In this example embodiment, m new samples are calculated for m samples by the Kernel ABC and the processing in Kernel Herding. Therefore, it can also be said that the value of the sample is adjusted.

While Kernel Herding is a method of sequentially determining samples, the predetermined processing for acquiring the samples that follow the posterior distribution (in this example embodiment, the estimated posterior distribution) is not limited to Kernel Herding. That is, it is sufficient that the predetermined processing be a method of generating samples that follow the posterior distribution (in this example embodiment, the estimated posterior distribution).

In this example embodiment, as shown in Expression (3), the sample data of the parameter θ that follows the posterior distribution including the inverse temperature β is acquired. In particular, the information processing apparatus 100 that acquires the sample data using the Kernel ABC and Kernel Herding will be described.

It can also be said that the inverse temperature β indicates a value indicating the level at which the influence of the distribution calculated based on each of the samples on the estimated distribution is leveled in processing of estimating the posterior distribution. In this case, the higher the inverse temperature β becomes, the lower the level to be leveled becomes. In other words, as the inverse temperature β becomes higher, the estimated distribution is more affected by each distribution. On the other hand, the lower the inverse temperature β becomes, the higher the level to be leveled becomes. In other words, as the inverse temperature β becomes lower, the estimated distribution is less affected by some distributions. It can also be said that the inverse temperature β indicates the degree of influence indicating the degree of influence of the sample on the estimated distribution. That is, it can also be said that the inverse temperature β indicates the degree of influence of the sample on the estimated distribution.

Next, a method of estimating the posterior distribution of the parameters θ according to this example embodiment will be described. In this example embodiment, the sample of the posterior distribution of the parameters θ is acquired by iteratively executing parameter estimation processing by Kernel ABC and Kernel Herding. That is, in this example embodiment, the parameter estimation processing is repeated using the sample of the posterior distribution of the parameters θ acquired in the parameter estimation processing, which is regarded as a sample from the prior distribution, whereby the sample of the posterior distribution of the parameters θ is acquired. This process will be described using a mathematical expression. The information processing apparatus 100 performs the iteration of the aforementioned processing T times. Note that T is an integer equal to or larger than two. It is further assumed that the value of the inverse temperature used in the t-th (where t=1, 2, . . . , T) iteration processing is β^{(t)}. It is assumed here that the total value of β^{(t)} set in each iteration processing is 1. That is, it is assumed that the following Expression (4) is established. Here, 0<β^{(t)}<1.

Σₜ₌₁^{T}β^{(t)}=1 <Expression (4)>

In other words, in the above case, the degree of influence of each iteration is set in such a way that the total value of the degree of influence for the number of iterations becomes 1.

In the first iteration processing (t=1), i.e., in the first parameter estimation processing, the posterior distribution expressed by the following Expression (5) is obtained based on Bayes' theorem (see Expression (3)). In the first parameter estimation processing, a second predetermined number of parameters are obtained based on a first predetermined number of samples obtained from the prior distribution of the parameters θ. While the number of samples obtained from the prior distribution (i.e., the first predetermined number) and the number of samples obtained as the result of the parameter estimation processing (i.e., the second predetermined number) are both m in this example embodiment, they may be different from each other. Note that the larger the number of samples becomes, the more appropriately the distribution can be expressed.

p⁽¹⁾(θ|x,y)∝p(y|x,θ)^{β}^{⁽¹⁾}π(θ) <Expression (5)>

The symbol “∝” indicates a proportional relation. The second iteration processing is performed using the posterior distribution p⁽¹⁾(θ|x,y) obtained in the first iteration processing, which is regarded as the prior distribution. That is, the parameter estimation processing is performed again using a sample obtained as a result of the first iteration processing. As a result, the obtained posterior distribution (the posterior distribution p⁽²⁾(θ|x,y) obtained in the second iteration processing) is expressed by the following Expression (6).

p⁽²⁾(θ|x,y)∝p(y|x,θ)^{β}^{⁽²⁾}p(y|x,θ)^{β}^{⁽¹⁾}π(θ)=p(y|x,θ)^{β}^{⁽¹}^{+β}^{⁽²⁾}π(θ) <Expression (6)>

Likewise, the third iteration processing is performed using the posterior distribution p⁽²⁾(θ|x,y) obtained in the second iteration processing, which is regarded as the prior distribution. Therefore, the posterior distribution p^{(T)}(θ|x,y) obtained in the T-th iteration processing can be expressed by the following Expression (7).

$${p}^{( T )} ( θ \vert x , y ) ∝ {p ( y \vert x , θ )}^{{\sum }_{t = 1}^{T} {β}^{( t )}} π ( θ ) \qquad < Expression ( 7 ) >$$

That is, by using Expression (4), the posterior distribution p^{(T)}(θ|x,y) can be expressed by the following Expression (8).

p^{(T)}(θ|x,y)∝p(y|x,θ)π(θ) <Expression (8)>

Expression (8) indicates Bayes' theorem that does not include an inverse temperature. That is, this expression indicates that Bayesian estimation is being performed. While the method disclosed in Non-Patent Literature 1 is maximum likelihood estimation, that is, point estimation, in the method shown in this example embodiment, the estimation of the distribution can be performed by repeating the parameter estimation processing that uses an inverse temperature.

Hereinafter, the information processing apparatus 100 will be described in detail.

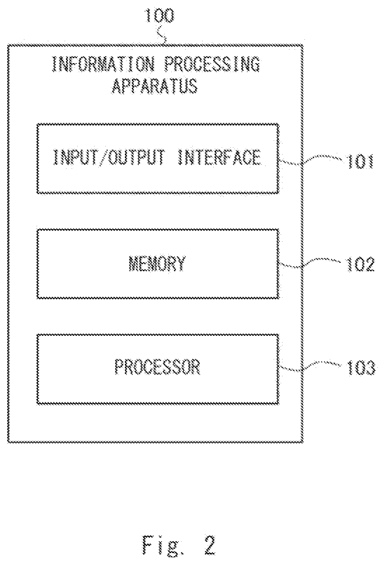

FIG. 2 is a block diagram showing one example of a hardware configuration of the information processing apparatus 100. The information processing apparatus 100 includes an input/output interface 101, a memory 102, and a processor 103.

The input/output interface 101 is an interface that inputs/outputs data. The input/output interface 101 is used, for example, to communicate with another apparatus. In this case, the input/output interface 101 is used, for example, to communicate with the simulator server 200. The input/output interface 101 may be used to communicate with an external apparatus such as a sensor apparatus that outputs the observation data Xⁿ or the observation data Yⁿ. Further, the input/output interface 101 may further include an interface connected to an input device such as a keyboard and a mouse. In this case, the input/output interface 101 acquires data input by user's operations. Further, the input/output interface 101 may further include an interface connected to a display. In this case, for example, operation results of the information processing apparatus 100 and the like are displayed on a display via the input/output interface 101.

The memory 102 includes, for example, a combination of a volatile memory and a non-volatile memory. The memory 102 is used to store various kinds of data used for the processing of the information processing apparatus 100, software (computer program) or the like including one or more instructions executed by the processor 103.

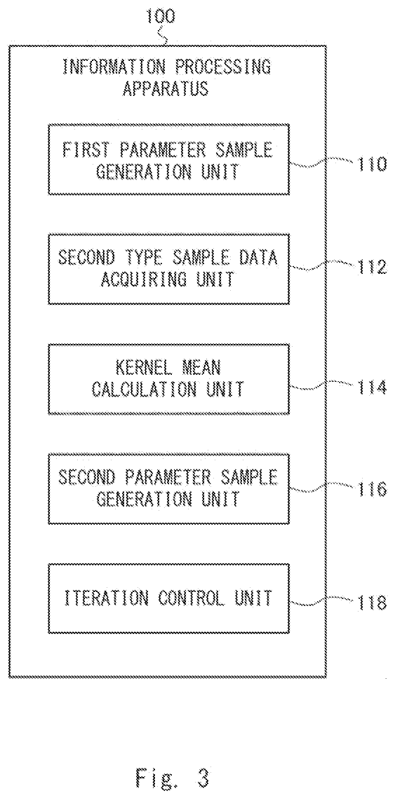

The processor 103 loads software (computer program) from the memory 102 and executes the loaded software, thereby performing processing of the respective components shown in FIG. 3 that will be described later. The processor 103 may be, for example, a microprocessor, a Micro Processor Unit (MPU), or a Central Processing Unit (CPU). The processor 103 may include a plurality of processors.

Further, the above-described program can be stored and provided to a computer using any type of non-transitory computer readable media. Non-transitory computer readable media include any type of tangible storage media. Examples of non-transitory computer readable media include magnetic storage media (such as flexible disks, magnetic tapes, hard disk drives, etc.), optical magnetic storage media (e.g., magneto-optical disks), CD-Read Only Memory (CD-ROM), CD-R, CD-R/W, and semiconductor memories (such as mask ROM, Programmable ROM (PROM), Erasable PROM (EPROM), flash ROM, Random Access Memory (RAM), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g., electric wires, and optical fibers) or a wireless communication line.

FIG. 3 is a block diagram showing one example of a functional configuration of the information processing apparatus 100. The information processing apparatus 100 includes a first parameter sample generation unit 110, a second type sample data acquiring unit 112, a kernel mean calculation unit 114, a second parameter sample generation unit 116, and an iteration control unit 118. The first parameter sample generation unit 110 is also referred to as an apriori parameter sample generation unit, the kernel mean calculation unit 114 is also referred to as a corresponding data calculation unit, and the second parameter sample generation unit 116 is also referred to as a new parameter sample generation unit.

The first parameter sample generation unit 110 generates the sample data of the parameter θ based on the prior distribution π(θ) of the parameter θ of the regression model r(x,θ) that outputs the data of the second type (data Y) upon receiving the input of the data of the first type (data X). The prior distribution π(θ) is, for example, a uniform distribution. When the prior distribution π(θ) is a uniform distribution, the sample data is randomly selected from a domain where the value of θ is defined. When the distribution that is estimated to be close to the posterior distribution to some extent is obtained, this distribution may be set to be the prior distribution π(θ). In this case, the sample data is selected from this domain in accordance with the prior distribution π(θ). The prior distribution π(θ) is not limited to the above-described example and it is not necessarily explicitly given. When the prior distribution π(θ) is not explicitly given, the prior distribution π(θ) is set, for example, to be a uniform distribution. Further, as will be described later, the prior distribution π(θ) may be set by the user.

That is, when the number of pieces of sample data generated by the first parameter sample generation unit 110 is denoted by m (m is a positive integer) and j denotes an integer that satisfies 1≤j≤m, the sample data of the parameter θ is expressed as shown in the following Expression (9). The symbol d_{θ} denotes the number of dimensions of the parameters (i.e., the number of types of the parameters θ). That is, Expression (9) indicates that the number of sets including de types of parameters is m. The symbol R denotes a real number.

As shown in Expression (9), the sample data of the parameter θ is indicated as a de-dimensional real number and follows the prior distribution π(θ). The prior distribution π(θ) is stored in the memory 102 in advance. The prior distribution π(θ) is, for example, set in advance with an accuracy in accordance with the knowledge that the user has about the simulation target.

θ̅ⱼ∈ [symbol] ^{d}^{_{θ}}˜π(θ) for j=1, . . . ,m <Expression (9)>

In the first iteration processing described above, the second type sample data acquiring unit 112 operates as follows. The second type sample data acquiring unit 112 receives the parameter θ generated by the first parameter sample generation unit 110 and inputs the m received parameters θ into the simulator server 200 along with the observation data (observation data Xⁿ) of the data of the first type. Further, in the second and subsequent iteration processing, the second type sample data acquiring unit 112 operates as follows. The second type sample data acquiring unit 112 receives m samples regarding the parameter θ generated by a second parameter sample generation unit 116 that will be described later in accordance with the control of the iteration control unit 118 that will be described later. Then the second type sample data acquiring unit 112 inputs the m received parameters θ to the simulator server 200 along with the observation data (observation data Xⁿ) of the data of the first type.

In this manner, the m parameters θ and the observation data (observation data Xⁿ) of the data of the first type are input to the simulator server 200.

The simulator server 200 executes, for each of the m input parameters θ, simulation calculation based on the observation data (observation data X′) of the data of the first type. That is, the simulator server 200 executes m types of simulation calculations regarding the observation target in accordance with the m input parameters θ. The simulator server 200 executes m types of simulation calculations, thereby calculating m types of simulation results (Y̅ⁿ).

The second type sample data acquiring unit 112 acquires them types of simulation results from the simulator server 200 as sample data of the second type. The above-described processing can be mathematically expressed as follows.

The second type sample data acquiring unit 112 acquires, for each of the pieces of the sample data of the parameter, sample data that has n (the same number as the number of elements of the observation data Xⁿ) elements and is expressed as shown in Expression (10) from the model (simulator server 200).

Y̅ⱼⁿ∈ [symbol] ⁿ˜p(y|θ̅ⱼ) <Expression (10)>

As shown in Expression (10), the sample data acquired by the second type sample data acquiring unit 112 is indicated as an n-dimensional real number and follows the distribution in which the sample data of the parameter is input to the likelihood function p(y|θ) of the regression model r(x,θ).

The kernel mean calculation unit 114 estimates the kernel mean indicating the posterior distribution of the parameters in accordance with the Kernel ABC. That is, the kernel mean calculation unit 114 calculates the kernel mean indicating the posterior distribution of the parameters based on the sample data of the parameter and the sample data of the second type. In particular, the kernel mean calculation unit 114 calculates the kernel mean using the kernel function including the inverse temperature.

Now, the Kernel ABC will be described. In the Kernel ABC, the kernel mean expressed by the following Expression (11) is calculated using the sample data expressed by Expression (9) and the sample data expressed by Expression (10). The kernel mean corresponds to the posterior distribution expressed on a Reproducing Kernel Hilbert Space (RKHS) by Kernel Mean Embeddings. The kernel mean is one example of data that corresponds to the distribution of the parameters (posterior distribution).

$${\hat{μ}}_{θ} \vert Y = {\sum }_{j = 1}^{m} {ω}_{j} {\overline{θ}}_{j} ∈ \qquad < Expression ( 11 ) >$$

The weight wⱼ is expressed as shown in the following Expression (12). The symbol H denotes a Reproducing Kernel Hilbert Space. That is, the larger the weight (importance) wⱼ becomes, the stronger the influence of the kernel regarding the sample

θ̅ⱼ

on the mean becomes. The smaller the weight wⱼ becomes, the weaker the influence of the kernel regarding the sample

θ̅ⱼ

on the mean becomes.

$$\begin{matrix}w = {( {ω}_{1} , … , {ω}_{m} )}^{T} ∈ {ℝ}^{m} \\ = {( G + m δ I )}^{- 1} {k}_{y} ( {Y}^{n} ) .\end{matrix} \qquad < Expression ( 12 ) >$$

Note that the superscript T indicates transposition of a matrix or a vector. Further, I denotes an identity matrix and δ (where δ>0) denotes a regularization constant. Further, the vector k_{y}(Yⁿ) and a Gram Matrix G are expressed as shown in the following Expressions (13) and (14) by the kernel k_{y} with respect to the data vector Yⁿ composed of an element of a real number. The symbol k_{y}(Yⁿ) denotes a function of calculating the closeness (norm) between the observation data Yⁿ and the sample data in Expression (10) that corresponds to the above observation data Yⁿ, i.e., the similarity between them. In other words, from Expression (13), the similarity between each of m types of simulation results that the simulator server 200 has output with respect to the observation data (observation data Xⁿ) and the observation data that the observation target has actually output with respect to the observation data. The kernel mean is a weighted mean that is calculated in accordance with the processing shown in Expression (11) using the weight of each parameter determined using the calculated similarity.

k_{y}(Yⁿ)=(k_{y}(Y̅₁ⁿ,Yⁿ), . . . ,k_{y}(Y̅ₘⁿ,Yⁿ))^{T}∈ [symbol] ^{m×m} <Expression (13)>

G=(k_{y}(Y̅ⱼⁿ,Y̅_{j′}ⁿ))_{j,j′=1}^{m}∈ [symbol] ^{m×m} <Expression (14)>

It can also be said that Expression (13) calculates the difference between a plurality of pieces of observation information observed when the input is given to the observation target and the data of the second type generated by the simulator server 200 with respect to the plurality of samples and the data of the first type indicating the input. Further, it can also be said that Expression (11) expresses processing of calculating a large weight for data that is similar to the observation data that has been actually observed regarding the observation target among m types of simulation results. Likewise, it can also be said that Expression (11) expresses processing of calculating a small weight for data that is not similar to the observation data that has been actually observed regarding the observation target among the m types of simulation results. That is, it can also be said that Expression (12) calculated using Expression (13) expresses processing of calculating a weight in accordance with the degree that the result of the simulation and the observation data are similar to each other. It can also be said that this is processing that uses Covariate Shift.

In the Kernel ABC with respect to Covariate Shift, while the distribution q₀(x) that the training data set {Xⁿ,Yⁿ} follows is different from the distribution q₁(x) that the data set for testing or predicting follows, a real function relation p(y|x) is the same. That is, Covariate Shift indicates that, while the processing of calculating y with respect to a given x is constant for a plurality of x, the distribution, which is the input, at the time of training is different from that at the time of testing. It is assumed here that the probability densities q₀(x) and q₁(x) have already been given or the ratio thereof q₀(x)/qᵢ(x) has already been given. In this case, as this ratio becomes closer to 1, it is indicated that q₀(x) at the time of training and q₁(x) at the time of testing occur at probabilities similar to each other. As this ratio becomes larger than 1, it is indicated that the probability at the time of training becomes higher than that at the time of testing. Further, as this ratio becomes smaller than 1, the probability at the time of testing becomes higher than that at the time of training. That is, this ratio is an index indicating which one of the distribution at the time of training and the distribution at the time of testing the data x is close to. This index is not limited to the ratio and may be, for example, an index indicating the difference between the distribution at the time of training and the distribution at the time of testing, like the difference between both distributions. When the probability densities q₀(x) and q₁(x) have already been given or when the ratio of them q₀(x)/q₁(x) has already been given, the kernel function k_{y} on the right side of Expressions (13) and (14) can be expressed as shown in the following Expression (15). Expression (15) corresponds to Expression (20) that will be shown later except for the difference regarding whether or not the inverse temperature depends on the training data (observation data).

$${k}_{y}^{( {β}_{i} )} ( {Y}^{n} , {Y}^{{n}^{′}} ) = exp \{ - \frac{1}{2 {σ}^{2}} {\sum }_{i = 1}^{n} {{β}_{i} ( {Y}_{i} - {Y}_{i}^{′} )}^{2} \} \qquad < Expression ( 15 ) >$$

Note that (Yⁿ,Yⁿ′) on the left side of Expression (15) indicates that the kernel function is a function of two variables (note that the two variables are both vectors) regarding the data of the second type expressed by an n-dimensional vector (a data set whose number of elements is n (i.e., including n elements)). That is, Yⁿ on the left side indicates a first variable in the function of two variables and Yⁿ′ on the left side indicates a second variable in the function of two variables. Then Yᵢ on the right side indicates the i-th element of the n-dimensional vector input to the function of two variables as the first variable. Further, Yᵢ′ on the right side indicates the i-th element of the n-dimensional vector input to the function of two variables as the second variable.

In Expression (15), σ is a standard deviation of the Gaussian noise regarding the data of the second type. More specifically, in Expression (15), σ is a standard deviation of the distribution composed of the whole observation data of the data of the second type used to calculate Expression (15). In particular, it can be said that 6 in Expression (15) means a value indicating a scale for measuring the similarity between the distribution of the observation data of the second type and the distribution of the sample data of the second type. Further, n denotes the number of pieces of data of the second type and βᵢ denotes the inverse temperature, and Yᵢ and Yᵢ′ each denote a value of the data of the second type. That is, in Expression (15), each of the elements included in the data set of the second type (e.g., the type of the observation data) is weighted by βᵢ, which is the inverse temperature. In other words, by appropriately setting βᵢ, which is the inverse temperature, it becomes possible to give different priorities to each type of the data of the second type.

In Expression (15), βᵢ denotes the inverse temperature that depends on the training data (observation data) {Xᵢ,Yᵢ}. That is, values of the inverse temperatures may be set so as to be different from one another for each of the pieces of data. That is, the inverse temperature βᵢ can be set for each of the types of the observation data (i.e., elements included in Yⁿ). For example, a larger value is set for the inverse temperature for a type of observation data whose importance level is high and a smaller value is set for the inverse temperature for a type of observation data whose importance level is low.

In this example embodiment, the kernel mean is calculated for an inverse temperature that does not depend on the training data (observation data) {Xᵢ,Yᵢ}. Specifically, the kernel mean calculation unit 114 calculates the kernel mean indicated by the following Expression (16).

$${\hat{μ}}_{ϑ \vert YX} = {\sum }_{j = 1}^{m} {\tilde{w}}_{j} {\overline{θ}}_{j} \qquad < Expression ( 16 ) >$$

The weight

\tilde{w}ⱼ

is indicated as shown in the following Expression (17).

$$\begin{matrix}\begin{matrix}\tilde{w} = {( {\tilde{ω}}_{1} , … , {\tilde{ω}}_{m} )}^{T} ∈ {ℝ}^{m} \\ = {( \tilde{G} + m δ I )}^{- 1} {\tilde{k}}_{y} ( {Y}^{n} ) .\end{matrix} & \end{matrix} \qquad < Expression ( 17 ) >$$

The vector

\tilde{k}_{y}(Yⁿ).

and the gram matrix

\tilde{G}

are indicated as shown by the following Expressions (18) and (19) by the kernel

\tilde{k}_{y}

with respect to the data vector Yⁿ composed of an element of a real number.

\tilde{k}_{y}(Yⁿ)=(\tilde{k}_{y}(Y̅₁ⁿ,Yⁿ), . . . ,\tilde{k}_{y}(Y̅ₘⁿ,Yⁿ))^{T}∈ [symbol] ^{m} <Expression (18)>

\tilde{G}=(\tilde{k}_{y}(Y̅ⱼⁿ,Y̅_{j′}ⁿ))_{j,j′=1}^{m}∈ [symbol] ^{m×m} <Expression (19)>

Here, the kernal function on the right side in Expressions (18) and (19)

\tilde{k}_{y}

can be expressed as shown in the following Expression (20).

$${\tilde{k}}_{y} ( {Y}^{n} , {Y}^{{n}^{′}} ) = exp \{ - \frac{1}{2 {σ}^{2}} {\sum }_{i = 1}^{n} {β ( {Y}_{i} - {Y}_{i}^{′} )}^{2} \} \qquad < Expression ( 20 ) >$$

Note that (Yⁿ,Yⁿ′) on the left side of Expression (20) indicates that the kernel function is a function of two variables (these two variables are both vectors) regarding the data of the second type expressed by an n-dimensional vector (a data set whose number of elements is n (i.e., including n elements)). That is, Yⁿ on the left side denotes the first variable in the function of two variables and Yⁿ′ on the left side denotes the second variable in the function of two variables. The symbol Yᵢ on the right side denotes the i-th element of the n-dimensional vector input to the function of two variables as the first variable. Further, the symbol Yᵢ′ on the right side denotes the i-th element of the n-dimensional vector input to the function of two variables as the second variable.

When the processing shown in Expression (15) is compared with the processing shown in Expression (20), each of the elements included in the data set of the second type (e.g., type of the observation data) is weighted by βᵢ, which is the inverse temperature in Expression (15). On the other hand, in Expression (20), the elements included in the data set of the second type (e.g., type of the observation data) are weighted by one inverse temperature.

In Expression (20), σ is a standard deviation of Gaussian noise regarding the data of the second type. More specifically, in Expression (20), σ is a standard deviation of the distribution composed of the entire observation data of the data of the second type used to calculate Expression (20). In particular, it can be said that σ in Expression (20) indicates the value indicating the scale for measuring the similarity between the distribution of the observation data of the second type and the distribution of the sample data of the second type. Further, n denotes the number of pieces of data of the second type, β denotes the inverse temperature, and Yᵢ and Yᵢ′ are values of the data of the second type. The symbol β is a constant that does not depend on observation data. The symbol β corresponds to the aforementioned β^{(t)}. Therefore, to be specific, β⁽¹⁾ is used as the value of β in the first parameter estimation processing and β⁽²⁾ is used as the value of β in the second parameter estimation processing. Likewise, β^{(T)} is used as the value of β in the T-th parameter estimation processing.

The second parameter sample generation unit 116 generates the sample data of the parameters that follow the posterior distribution that is defined using the inverse temperature based on the kernel mean calculated by the kernel mean calculation unit 114. Here, the posterior distribution defined using the inverse temperature is defined from the prior distribution and the likelihood function controlled by the inverse temperature based on Bayes' theorem. Therefore, the posterior distribution is a distribution that follows exp(−βnLₙ(θ)+log π(θ)).

Specifically, the second parameter sample generation unit 116 generates the sample data of the parameters that follow the posterior distribution using Kernel Herding. In Kernel Herding, by the update expression shown in the following Expression (21) and (22), m pieces of sample data θ₁, . . . , θₘ that follow the posterior distribution are generated.

θⱼ₊₁=argmax_{θ}hⱼ(θ) <Expression (21)>

hⱼ₊₁=hⱼ+μ−θⱼ₊₁∈ [symbol] <Expression (22)>

Here, j=0, . . . , m−1. Further, argmax₀hⱼ(θ) indicates a value of θ that maximizes the value of hⱼ(θ). The symbol hⱼ is sequentially indicated by Expression (22). For the initial value ho of hⱼ and μ, the value of the kernel mean calculated in accordance with the processing shown in Expression (16) is used. That is, the second parameter sample generation unit 116 generates, using the kernel mean calculated by the kernel mean calculation unit 114, m pieces of sample data θ₁, . . . , θₘ that are suitable for expressing the kernel mean by predetermined processing such as Kernel Herding. In other words, the information processing apparatus 100 executes processing of calculating m pieces of sample data that follows the estimated posterior distribution for m pieces of sample data that follows the prior distribution. Therefore, it can also be said that the processing in the information processing apparatus 100 is processing of adjusting values of m pieces of sample data.

The iteration control unit 118 performs control so as to repeat the parameter estimation processing by Kernel ABC and Kernel Herding a predetermined number of times (T times). That is, the iteration control unit 118 performs control so as to enable the second type sample data acquiring unit 112 to use, in the (t+1)-th iteration processing, the sample generated by the second parameter sample generation unit 116 in the t-th iteration processing. Therefore, the kernel mean calculation unit 114 calculates, in the (t+1)-th processing, the kernel mean using the observation data Xⁿ and the sample generated by the second parameter sample generation unit 116 in the t-th iteration processing. Therefore, the iteration control unit 118 can also be described as follows. That is, the iteration control unit 118 performs control so as to calculate the kernel mean using the data of the second type generated by the simulator server 200 with respect to the sample generated by the second parameter sample generation unit 116 and the data of the first type. The iteration control unit 118 then performs control so as to repeat the parameter estimation processing while performing the above control.

Note that the iteration control unit 118 may set the value of the inverse temperature β used in each parameter estimation processing. As described above, the total value of 13 set in the respective iterations is 1. Specifically, for example, the inverse temperature to be set may be constant regardless of the iteration of the parameter estimation processing or may be changed in accordance with the iteration of the parameter estimation processing.

When the constant inverse temperature is set regardless of the iteration of the parameter estimation processing, the iteration control unit 118 sets β^{(t)}=1/T as a value of the inverse temperature.

When the inverse temperature that varies in accordance with the iteration of the parameter estimation processing is set, for example, the inverse temperature may be set to become smaller in accordance with the number of times the parameter estimation processing is repeated. In other words, in the iteration, a value that is equal to or smaller than the previous value may be set as the degree of influence, and at least once in the iteration, a value smaller than the previous value may be set as the degree of influence. Further, the inverse temperature may be set to become larger in accordance with the number of times the parameter estimation processing is repeated. In other words, in the iteration, a value that is equal to or larger than the previous value may be set as the degree of influence, and at least once in the iteration, a value larger than the previous value may be set as the degree of influence.

When the inverse temperature that varies in accordance with the iteration of the parameter estimation processing is set, the iteration control unit 118 may set the value of the inverse temperature based on a predetermined geometric progression. Infinite geometric series, which is a summation of infinite terms of a geometric progression with the first term a and the common ratio r (where −1<r<1) converges to a/(1−r). The iteration control unit 118 may therefore use, for example, a geometric progression expressed by given a and r that satisfy a/(1−r)=1 so as to satisfy Expression (4).

For example, the values of the respective terms of the geometric progression may be used as the values of the inverse temperatures set in the respective parameter estimation processes in order from the first term. In this case, the inverse temperature is set to become smaller in accordance with the number of times the parameter estimation processing is repeated. In reality, however, the number of times the parameter estimation processing is repeated is a finite number. Therefore, for example, the iteration control unit 118 may set the inverse temperature as follows. Specifically, the iteration control unit 118 sets the values of the respective terms of the geometric progression whose number of terms is T−1 as values of inverse temperatures from the first parameter estimation processing to the (T−1)-th parameter estimation processing in order from the first term. Then, in the T-th parameter estimation processing, the value of the (T−1)-th term of the geometric progression is set as a value of the inverse temperature again. In this manner, the iteration control unit 118 may determine the inverse temperature this time so that this inverse temperature becomes equal to or smaller than the inverse temperatures that have been previously set in the respective iterations.

Further, the values of the respective terms of the geometric progression may be used as the values of the inverse temperatures set in the respective parameter estimation processes in order from the last term. In this case, the inverse temperature is set to become larger in accordance with the number of times the parameter estimation processing is repeated. In this case as well, the setting may be performed as follows in such a way that the sum of geometric progression consisting of a finite number of terms becomes 1. For example, the iteration control unit 118 first sets, in the first parameter estimation processing, a value of the (T−1)-th term in the geometric progression whose number of terms is T−1 as a value of the inverse temperature. Then, as values of the inverse temperatures from the second parameter estimation processing to the T-th parameter estimation processing, the values of the respective terms of the geometric progression are set in order from the last term. In this manner, the iteration control unit 118 may determine the inverse temperature this time so that this inverse temperature becomes equal to or larger than the inverse temperatures that have been previously set in the respective iterations.

As described above, the inverse temperature may be arbitrarily set. As shown in Expression (5), (6), or (7), the posterior distribution is proportional to a product of a likelihood function and the prior distribution and the inverse temperature is an exponent with respect to the likelihood function. Therefore, the setting of the inverse temperature indicates the degree to which the influence of the likelihood function is reflected on the posterior distribution. Therefore, the way in which the inverse temperature is set in the repeated parameter estimation processing may be defined depending on the reliability of the likelihood function to be used. When, for example, the reliability of the likelihood function is high, in the first parameter estimation processing, a value larger than the inverse temperatures in the subsequent iterations may be set as the inverse temperature. On the other hand, when the reliability of the likelihood function is low, in the first parameter estimation processing, a value smaller than the inverse temperatures in the subsequent iterations may be set as the inverse temperature. Further, the way in which the inverse temperature is set in the repeated parameter estimation processing may be defined depending on the reliability of the prior distribution to be used. When, for example, the reliability of the prior distribution is high, in the first parameter estimation processing, a value smaller than the inverse temperatures in the subsequent iterations may be set as the inverse temperature. On the other hand, when the reliability of the prior distribution is low, in the first parameter estimation processing, a value larger than the inverse temperatures in the subsequent iterations may be set as the inverse temperature.

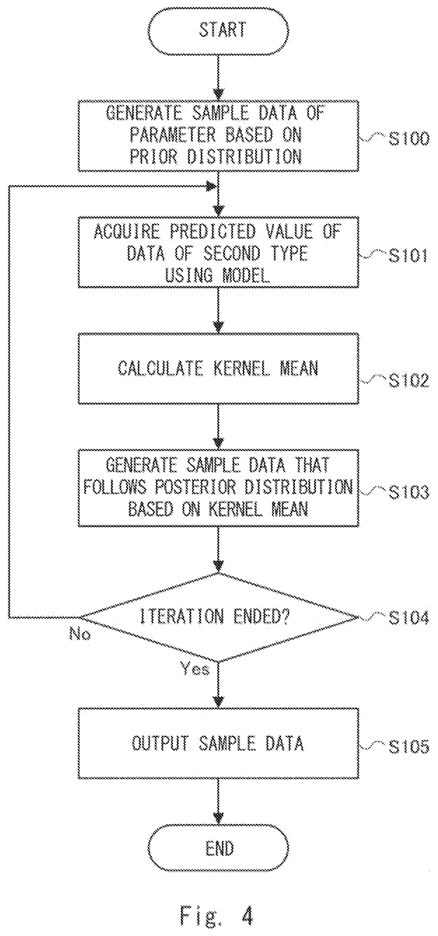

Next, an operation of the information processing apparatus 100 will be described based on a flowchart. FIG. 4 is a flowchart showing one example of the operation of the information processing apparatus 100. Hereinafter, with reference to FIG. 4, this operation will be described.

In Step S100, the first parameter sample generation unit 110 generates sample data of the parameter θ based on the prior distribution π(θ). The sample data generated by the first parameter sample generation unit 110 is input to the simulator server 200 in the first parameter estimation processing. In this example embodiment, as one example, the generated sample data is input to the simulator server 200 by the second type sample data acquiring unit 112.

Next, in Step S101, the second type sample data acquiring unit 112 acquires the sample data of the second type calculated by the simulator server 200. That is, the second type sample data acquiring unit 112 inputs X″, which is the data of the first type, of the training data set {Xⁿ,Yⁿ} acquired in advance, to a model, and acquires the output from the model. The training data set {Xⁿ,Yⁿ} is information in which Xⁿ, which is the data of the first type, is associated with Yⁿ, which is the data of the second type. In this case, Yⁿ, which is the data of the second type, indicates, for example, information observed regarding the observation target by the observation target actually performing processing (operation) on Xⁿ, which is the data of the first type.

As described above, the simulator server 200 calculates the data Y by performing the operation in accordance with the value indicated by the parameter θ on the value of the data X. Accordingly, the processing (operation) in the observation target is simulated. In this case, the parameter θ indicates, for example, the relationship between the input and the output in each processing (operation).

When the first parameter estimation processing is performed, in Step S101, the second type sample data acquiring unit 112 acquires the sample data of the second type calculated in accordance with a model in which the sample data generated in Step S100 is set as a parameter. On the other hand, in the second and subsequent parameter estimation processing, the second type sample data acquiring unit 112 sets the sample data generated in Step S103 that will be described later as a parameter of the model. The second type sample data acquiring unit 112 then acquires the sample data of the second type calculated in accordance with the model.

In Step S101, the simulator server 200 receives, as an input, Xⁿ, which is the data of the first type, indicating the input given to the observation target and performs the processing in accordance with the input parameter θ on Xⁿ, which is the data of the first type, thereby simulating the observation target. As a result, the simulator server 200 generates simulation results (Y̅ⁿ) indicating the results of the simulation.

Next, in Step S102, the kernel mean calculation unit 114 calculates the kernel mean indicating the posterior distribution of the parameters by Kernel ABC using the obtained sample data. As described above, this posterior distribution is defined using the inverse temperature. The kernel mean calculation unit 114 calculates the kernel mean using the kernel function including the inverse temperature shown by Expression (20). In other words, the kernel mean calculation unit 114 determines the importance of the respective samples of the parameters in accordance with the difference between the observation data regarding the data of the second type and the sample data and the inverse temperature, thereby calculating the data that corresponds to the distribution of the parameters.

Next, in Step S103, the second parameter sample generation unit 116 generates the sample data of the parameters that follow the posterior distribution defined using the inverse temperature based on the kernel mean calculated in Step S102.

Next, in Step S104, the iteration control unit 118 determines whether or not the number of times the parameter estimation processing is repeated has reached a predetermined number of times (T). When the number of iterations has not reached the predetermined number of times, the iteration control unit 118 performs control so that processing from Step S101 to Step S103 is performed again using the sample data obtained in Step S103. When the number of iterations has reached the predetermined number of times, in Step S105, the iteration control unit 118 outputs the sample data group obtained in Step S103 as the posterior distribution of the parameters.

The example embodiment has been described above. In this example embodiment, the parameter estimation processing using the inverse temperature is repeated. Accordingly, Bayesian estimation is performed and the posterior distribution of the parameters can be acquired. In particular, since the parameter estimation processing is Bayesian estimation iteratively executed, it is expected that an appropriate sample will be acquired also for a model such as a singular model where it seems to be difficult to acquire an appropriate sample of a posterior distribution in one parameter estimation process. For example, a posterior distribution can be estimated also for a singular model such as a neural network. Further, since the parameter estimation processing is iteratively executed, it is expected that an appropriate sample will be acquired even when the prior distribution is not appropriate.

The sample data of the parameter output in Step S105 in FIG. 4 may also be used for performing simulation by the simulator server 200. That is, the iteration control unit 118 may input the sample data generated in Step S103 at the last of the iteration processing (i.e., the sample data of the parameter θ) into the simulator server 200. In this case, the simulator server 200 receives m pieces of the sample data and executes the simulation calculation regarding the observation target based on the received sample data. Specifically, the simulator server 200 executes m kinds of simulation processing in accordance with the sample data for Xⁿ, which is the given data of the first type. As a result, the simulator server 200 calculates m types of simulation results for Xⁿ, which is the given data of the first type. The m types of simulation results are not necessarily different from one another and may include the same results.

After that, the information processing apparatus 100 receives m types of simulation results. Then the information processing apparatus 100 calculates simulation results in which m types of simulation results are synthesized. The information processing apparatus 100 calculates, for example, the average of m types of simulation results. That is, the information processing apparatus 100 calculates the simulation results for Xⁿ, which is the given data of the first type. The information processing apparatus 100 may calculate the simulation results for Xⁿ, which is the given data of the first type by calculating, for example, the weighted mean of m types of simulation results.

The information processing apparatus 100 executes the processing stated above with reference to FIG. 4, thereby calculating the sample data of the parameter θ in such a way that the simulation results calculated by the simulator server 200 match (conform to) the observation information Yⁿ. Since the calculated sample data is data that follows the posterior distribution, the aforementioned simulation results calculated by the information processing apparatus 100 are simulation results in accordance with the sample data that follows the posterior distribution. In other words, the information processing apparatus 100 is able to calculate the simulation results that match the observation information based on the simulation results generated by the simulator server 200. Therefore, by generating a value that conforms to the observation information regarding the sample data of the parameter θ given to the simulator server 200, the information processing apparatus 100 is able to calculate the simulation results that conform to this observation information.

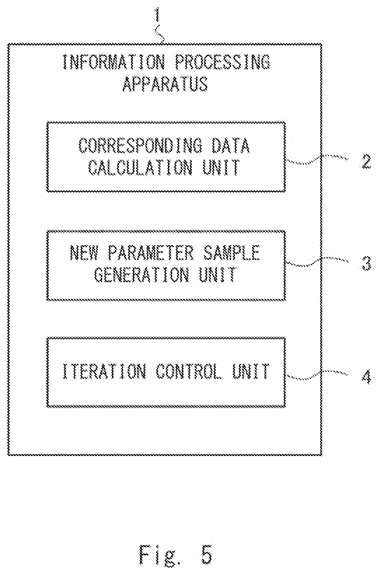

Note that the present disclosure is not limited to the above example embodiment and may be changed as appropriate without departing from the spirit of the present disclosure. For example, the following information processing apparatus 1 is also one example embodiment. FIG. 5 is a block diagram showing a configuration of an information processing apparatus 1. The information processing apparatus 1 includes a corresponding data calculation unit 2, a new parameter sample generation unit 3, and an iteration control unit 4.

The corresponding data calculation unit 2 determines the importance of the respective samples of the parameters based on the difference between the plurality of pieces of observation information (Yⁿ) observed when the input (Xⁿ) has been given to the observation target and the data of the second type (Y̅ⁿ), and the inverse temperature (β). The data of the second type is data generated by the simulator that simulates the observation target based on the samples of the parameters with respect to the plurality of samples and the data of the first type indicating the input. Then the corresponding data calculation unit 2 calculates the data that corresponds to the distribution of the parameters.

The new parameter sample generation unit 3 generates new samples of the parameters in accordance with predetermined processing (e.g., Kernel Herding) using the data that corresponds to the distribution of the parameters calculated by the corresponding data calculation unit 2.

Further, the iteration control unit 4 performs control so that the corresponding data calculation unit 2 calculates the data that corresponds to the distribution of the parameters using the data of the second type generated by the simulator with respect to the new sample generated by the new parameter sample generation unit 3 and the data of the first type. The iteration control unit 4 then performs control so as to repeat processing of the corresponding data calculation unit 2 and the processing of the new parameter sample generation unit 3.

According to the above configuration, Bayesian estimation is performed. The information processing apparatus 1 is therefore able to acquire posterior distribution of the parameters.

The whole or part of the example embodiments disclosed above can be described as, but not limited to, the following supplementary notes.

### (Supplementary Note 1)

An information processing apparatus comprising:

corresponding data calculation means for determining importance of each sample in accordance with a difference between a plurality of pieces of observation information observed when an input is given to an observation target and data of a second type generated by a simulator that simulates the observation target based on a sample of a parameter with respect to a plurality of samples and data of a first type indicating the input, and a degree of influence of the sample on distribution of parameters, and then calculating data that corresponds to the distribution of the parameters;

new parameter sample generating means for generating a new sample of the parameters in accordance with predetermined processing using the data that corresponds to the distribution of the parameters; and

iteration control means for performing control so as to repeat the processing of the corresponding data calculation means and the processing of the new parameter sample generation means while performing control so that the corresponding data calculation means calculates data that corresponds to the distribution of the parameters using the data of the second type generated by the simulator with respect to the new sample generated by the new parameter sample generation means and the data of the first type.

### (Supplementary Note 2)

The information processing apparatus according to Supplementary Note 1, wherein the degree of influence varies in accordance with iteration of the processing of the corresponding data calculation means and the processing of the new parameter sample generation means.

### (Supplementary Note 3)

The information processing apparatus according to Supplementary Note 2, wherein, in the iteration, a value that is equal to or smaller than the previous value is set as the degree of influence, and at least once in the iteration, a value smaller than the previous value is set as the degree of influence.

### (Supplementary Note 4)

The information processing apparatus according to Supplementary Note 2, wherein, in the iteration, a value that is equal to or larger than the previous value is set as the degree of influence, and at least once in the iteration, a value larger than the previous value is set as the degree of influence.

### (Supplementary Note 5)

The information processing apparatus according to Supplementary Note 3 or 4, wherein the degree of influence varies based on a predetermined geometric progression.

### (Supplementary Note 6)

The information processing apparatus according to Supplementary Note 1, wherein the degree of influence is constant regardless of the iteration of the processing of the corresponding data calculation means and the processing of the new parameter sample generation means.

### (Supplementary Note 7)

The information processing apparatus according to any one of Supplementary Notes 1 to 6, wherein

the data that corresponds to the distribution of the parameters is a kernel mean,

the corresponding data calculation means calculates the kernel mean using a kernel function including the degree of influence as an inverse temperature, and

the new parameter sample generation means generates the sample using the kernel mean calculated by the corresponding data calculation means.

### (Supplementary Note 8)

The information processing apparatus according to Supplementary Note 7, wherein the corresponding data calculation means calculates the kernel mean by Kernel Approximate Bayesian Computation (Kernel ABC) that uses the kernel function indicated by the following expression,

where σ denotes a standard deviation of Gaussian noise regarding the data of the second type, n denotes the number of elements of the data of the second type, β denotes the inverse temperature, and Yᵢ and Yᵢ′ denote values of the data of the second type.

$$exp \{ - \frac{1}{2 {σ}^{2}} {\sum }_{i = 1}^{n} {β ( {Y}_{i} - {Y}_{i}^{′} )}^{2} \}$$

### (Supplementary Note 9)

The information processing apparatus according to any one of Supplementary Notes 1 to 8, wherein the degree of influence of each iteration is set in such a way that the sum of the degree of influence for the number of iterations becomes 1.

### (Supplementary Note 10)

An information processing system comprising:

the information processing apparatus according to any one of Supplementary Notes 1 to 9; and

the simulator.

### (Supplementary Note 11)

The information processing system according to Supplementary Note 10, wherein the simulator executes processing based on the sample generated by the new parameter sample generation means after iteration of the processing of the corresponding data calculation means and the processing of the new parameter sample generation means.

### (Supplementary Note 12)

An information processing method for causing an information processing apparatus to execute:

first processing for determining importance of each sample in accordance with a difference between a plurality of pieces of observation information observed when an input is given to an observation target and data of a second type generated by a simulator that simulates the observation target based on a sample of a parameter with respect to a plurality of samples and data of a first type indicating the input, and a degree of influence of the sample on distribution of parameters, and then calculating data that corresponds to the distribution of the parameters;

second processing for generating a new sample of the parameters in accordance with predetermined processing using the data that corresponds to the distribution of the parameters; and

control so as to repeat the first processing and the second processing while performing control so as to execute the first processing using the data of the second type generated by the simulator with respect to the new sample generated by the second processing and the data of the first type.

### (Supplementary Note 13)

A non-transitory computer readable medium storing a program for causing a computer to execute:

a corresponding data calculation step for determining importance of each sample in accordance with a difference between a plurality of pieces of observation information observed when an input is given to an observation target and data of a second type generated by a simulator that simulates the observation target based on a sample of a parameter with respect to a plurality of samples and data of a first type indicating the input, and a degree of influence of the sample on distribution of parameters, and then calculating data that corresponds to the distribution of the parameters;

a new parameter sample generating step for generating a new sample of the parameters in accordance with predetermined processing using the data that corresponds to the distribution of the parameters; and

an iteration control step for performing control so as to repeat the processing of the corresponding data calculation step and the processing of the new parameter sample generating step while performing control so as to execute the corresponding data calculation step using the data of the second type generated by the simulator with respect to the new sample generated by the new parameter sample generation step and the data of the first type.

While the present disclosure has been described above with reference to the example embodiment, the present disclosure is not limited to the above example embodiment. Various changes that may be understood by those skilled in the art within the scope of the present disclosure can be made to the configurations and the details of the present disclosure.

This application is based upon and claims the benefit of priority from Japanese Patent Application No. 2018-219527, filed on Nov. 22, 2018, the disclosure of which is incorporated herein in its entirety by reference.

### REFERENCE SIGNS LIST

1 Information Processing Apparatus
2 Corresponding Data Calculation Unit
3 New Parameter Sample Generation Unit
4 Iteration Control Unit
10 Information Processing System
100 Information Processing Apparatus
101 Input/output Interface
102 Memory
103 Processor
110 First Parameter Sample Generation Unit
112 Second Type Sample Data Acquiring Unit
114 Kernel Mean Calculation Unit
116 Second Parameter Sample Generation Unit
118 Iteration Control Unit
200 Simulator Server

1. An information processing apparatus comprising:
at least one memory storing instructions; and
at least one processor configured to execute the instructions stored in the memory to:
execute first processing for determining importance of each sample in accordance with a difference between a plurality of pieces of observation information observed when an input is given to an observation target and data of a second type generated by a simulator that simulates the observation target based on a sample of a parameter with respect to a plurality of samples and data of a first type indicating the input, and a degree of influence of the sample on distribution of parameters, and then calculating data that corresponds to the distribution of the parameters;
execute second processing for generating a new sample of the parameters in accordance with predetermined processing using the data that corresponds to the distribution of the parameters; and
perform control so as to repeat the first processing and the second processing while performing control so as to execute the first processing using the data of the second type generated by the simulator with respect to the new sample generated by the second processing and the data of the first type.

2. The information processing apparatus according to claim 1, wherein the degree of influence varies in accordance with iteration of the first processing and the second processing.

3. The information processing apparatus according to claim 2, wherein, in the iteration, a value that is equal to or smaller than the previous value is set as the degree of influence, and at least once in the iteration, a value smaller than the previous value is set as the degree of influence.

4. The information processing apparatus according to claim 2, wherein, in the iteration, a value that is equal to or larger than the previous value is set as the degree of influence, and at least once in the iteration, a value larger than the previous value is set as the degree of influence.

5. The information processing apparatus according to claim 3, wherein the degree of influence varies based on a predetermined geometric progression.

6. The information processing apparatus according to claim 1, wherein the degree of influence is constant regardless of the iteration of the first processing and the second processing.

7. The information processing apparatus according to claim 1, wherein
the data that corresponds to the distribution of the parameters is a kernel mean, and
the processor is configured to execute the instructions to:
calculate the kernel mean using a kernel function including the degree of influence as an inverse temperature, and
generate the sample using the kernel mean calculated by the first processing.

8. The information processing apparatus according to claim 7, wherein the processor is configured to execute the instructions to calculate the kernel mean by Kernel Approximate Bayesian Computation (Kernel ABC) that uses the kernel function indicated by the following expression,
where σ denotes a standard deviation of Gaussian noise regarding the data of the second type, n denotes the number of elements of the data of the second type, β denotes the inverse temperature, and Y₁ and Yᵢ′ denote values of the data of the second type.
$$exp \{ - \frac{1}{2 {σ}^{2}} {\sum }_{i = 1}^{n} {β ( {Y}_{i} - {Y}_{i}^{′} )}^{2} \}$$

9. The information processing apparatus according to claim 1, wherein the degree of influence of each iteration is set in such a way that the sum of the degree of influence for the number of iterations becomes 1.

10.-11. (canceled)

12. An information processing method for causing an information processing apparatus to execute:
first processing for determining importance of each sample in accordance with a difference between a plurality of pieces of observation information observed when an input is given to an observation target and data of a second type generated by a simulator that simulates the observation target based on a sample of a parameter with respect to a plurality of samples and data of a first type indicating the input, and a degree of influence of the sample on distribution of parameters, and then calculating data that corresponds to the distribution of the parameters;
second processing for generating a new sample of the parameters in accordance with predetermined processing using the data that corresponds to the distribution of the parameters; and
control so as to repeat the first processing and the second processing while performing control so as to execute the first processing using the data of the second type generated by the simulator with respect to the new sample generated by the second processing and the data of the first type.

13. A non-transitory computer readable medium storing a program for causing a computer to execute:
a corresponding data calculation step for determining importance of each sample in accordance with a difference between a plurality of pieces of observation information observed when an input is given to an observation target and data of a second type generated by a simulator that simulates the observation target based on a sample of a parameter with respect to a plurality of samples and data of a first type indicating the input, and a degree of influence of the sample on distribution of parameters, and then calculating data that corresponds to the distribution of the parameters;
a new parameter sample generating step for generating a new sample of the parameters in accordance with predetermined processing using the data that corresponds to the distribution of the parameters; and
an iteration control step for performing control so as to repeat the processing of the corresponding data calculation step and the processing of the new parameter sample generating step while performing control so as to execute the corresponding data calculation step using the data of the second type generated by the simulator with respect to the new sample generated by the new parameter sample generation step and the data of the first type.
